(19) United States
(12) Patent Application Publication
(10) Pub. No.: US 2016/0126647 A1
(43) Pub. Date: May 5, 2016

(54) Communication Module

(71) Applicant: Hitachi Metals, Ltd., Tokyo (JP)

(72) Inventors: Yoshinori SUNAGA, Hitachinaka (JP); Masataka SATO, Hitachi (JP)

(21) Appl. No.: 14/828,930

(22) Filed: Aug. 18, 2015

(30) Foreign Application Priority Data
Oct. 31, 2014 (JP) 2014-223731

(51) Int. Cl. H01R 12/70; H01R 25/00; H05K 7/20

(52) U.S. Cl. CPC H01R 12/7076; H05K 7/2039; H01R 25/00

(57) ABSTRACT

A communication module includes: a housing having a plug connector which is inserted in a first direction into a receptacle connector provided on a motherboard and is removed in a second direction opposite to the first direction; a pair of slide members whose protrusion length with respect to the housing is variable and which has locking projections lockable and unlockable with locking holes provided in the motherboard; and a pull tab coupled to one ends of the respective slide members via a coupling member. The coupling member converts a force in the second direction applied to the pull tab into a force toward an inner side of the housing and transmits the converted force to the respective slide members, thereby moving the slide members to an inner side of the housing.

### CROSS-REFERENCE TO RELATED APPLICATION

The present application claims priority from Japanese Patent Application No. 2014-223731 filed on Oct. 31, 2014, the content of which is hereby incorporated by reference into this application.

### TECHNICAL FIELD OF THE INVENTION

The present invention relates to a communication module used for signal transmission between electronic devices and signal transmission inside an electronic device.

### BACKGROUND OF THE INVENTION

The amount of information handled between electronic devices and the amount of information handled inside an electronic device has increased year by year. In accordance with the increase in the information amount, the number of communication modules to be mounted in the electronic device has increased, and it is necessary to mount a plurality of the communication modules at high density in order to prevent the size increase of the electronic device.

Here, in a communication module and an electronic device in which the communication module is mounted, means for fixing them to each other is provided in some cases. For example, a slot having a locking hole is provided in a substrate (motherboard) of an electronic device. Meanwhile, a locking projection that is lockable and unlockable with the locking hole provided in the slot in the electronic device and an operating member for operating the locking projection are provided in the communication module. When the communication module is inserted into the slot of the electronic device, the locking projection protruding from a housing of the communication module is locked with the locking hole provided in the slot. Meanwhile, the locking projection locked with the locking hole is retracted to an inner side of the housing along with the operation of the operating member, thereby releasing the lock to the locking hole.

### SUMMARY OF THE INVENTION

When a plurality of communication modules are mounted at high density, a gap between the neighboring communication modules becomes narrow, so that there is a concern that it becomes impossible or difficult to have an access to the operating member provided in the respective communication modules or it becomes impossible or difficult to secure the operation amount (stroke amount) of the operating member. In addition, when the plurality of communication modules are mounted at high density, there is a concern that cables connected to the respective communication modules cross one another and the access to the operating member provided in the communication module is thus inhibited due to the cables.

An object of the present invention is to make it possible to easily and reliably operate means for fixing a communication module and a substrate even in the case in which the communication modules are mounted on the substrate at high density.

A communication module of the present invention is mounted on a substrate together with a plurality of other communication modules. One of the communication modules of the present invention includes: a housing having a first connector which is inserted in a first direction into a connector provided on the substrate and is removed in a second direction opposite to the first direction; a pair of slide members whose protrusion length with respect to the housing is variable and which has second locking portions that are lockable and unlockable with first locking portions that are directly or indirectly provided in the substrate; and an operating piece coupled to one ends of the respective slide members via a coupling member. The coupling member converts a force in the second direction applied to the operating piece into a force toward an inner side of the housing and transmits the converted force to the respective slide members, thereby moving the slide members to an inner side of the housing.

Another one of the communication modules of the present invention includes: a housing having a first connector which is inserted in a first direction into a connector provided on the substrate and is removed in a second direction opposite to the first direction; a pair of locking holes which is provided in the housing and which locking pieces directly or indirectly provided on the substrate can enter and can be disengaged from; a pair of slide members which is provided in the housing and is movable to inside and outside of the housing; and an operating piece coupled to one ends of the respective slide members via a coupling member. The coupling member converts a force in the second direction applied to the operating piece into a force toward an inner side of the housing and transmits the converted force to the one ends of the respective slide members, thereby moving the one ends of the slide members to an inner side of the housing. The other ends of the respective slide members whose one ends are moved to the inner side of the housing are moved to an outer side of the housing, thereby disengaging the locking pieces from the locking holes.

In one aspect of the communication module of the present invention, elastic members which bias the respective slide members toward an outer side of the housing are provided. The coupling member converts a force in the second direction applied to the operating piece into a force toward an inner side of the housing and transmits the converted force to the respective slide members, thereby moving the slide members to an inner side of the housing against the biasing of the elastic members.

In another aspect of the communication module of the present invention, the communication module is inserted into and removed from a slot that is provided on the substrate and encloses the connector, and the first locking portions are provided around an opening of the slot which the communication module is inserted into and removed from.

In another aspect of the communication module of the present invention, the coupling member includes: a base end portion to which the operating piece is coupled; a first end portion to which the one end of one of the slide members is coupled; a second end portion to which the one end of the other slide member is coupled; a first arm portion linking the base end portion and the first end portion; and a second arm portion linking the base end portion and the second end portion. An interval between the first arm portion and the second arm portion is expanded with distance from the base end portion. The coupling member is elastically deformed so that the first end portion and the second end portion come close to each other when a force in the second direction is applied to the base end portion.

In another aspect of the communication module of the present invention, a second connector which is provided on an opposite side of the first connector and which a communication cable is inserted into and removed from is provided. The pair of slide members is arranged at both sides of the second connector, the one end of one of the slide members is coupled to the first end portion of the coupling member at one side of the second connector, and the one end of the other slide member is coupled to the second end portion of the coupling member at the other side of the second connector. The operating piece is coupled to the base end portion of the coupling member in an insertion and removal direction of the communication cable.

In another aspect of the communication module of the present invention, inclined guide surfaces which abut on the respective slide members and guide movement of the slide members are provided in the housing.

According to the present invention, it is possible to easily and reliably operate means for fixing a communication module and a substrate even in the case in which the communication modules are mounted on the substrate at high density.

### BRIEF DESCRIPTIONS OF THE DRAWINGS

FIG. 1 is an exploded perspective view illustrating an example of an electronic device in which a communication module to which the present invention is applied is mounted;

FIG. 2 is a perspective view illustrating an example of the electronic device in which the communication module to which the present invention is applied is mounted;

FIG. 3 is a perspective view of the communication module according to the first embodiment;

FIG. 4 is a perspective view illustrating an internal structure of the communication module illustrated in FIG. 2;

FIG. 5 is a partially enlarged view of the communication module illustrated in FIG. 4;

FIG. 6 is a perspective view illustrating a coupling member and a pull tab;

FIG. 7 is a cross-sectional view illustrating a mounting state of the communication module illustrated in FIG. 2;

FIG. 8 is another cross-sectional view illustrating the mounting state of the communication module illustrated in FIG. 2;

FIG. 9 is a plan view illustrating an internal structure of a communication module according to the second embodiment;

FIG. 10 is a partially enlarged view of the communication module illustrated in FIG. 9;

FIG. 11 is a cross-sectional view illustrating an internal structure of a communication module according to the third embodiment; and

FIG. 12 is a partially enlarged view of the communication module illustrated in FIG. 11.

### DESCRIPTIONS OF THE PREFERRED EMBODIMENTS

### First Embodiment

Hereinafter, an example of an embodiment of a communication module of the present invention will be described. The communication module according to the first embodiment is mounted in an electronic device (not illustrated) together with a plurality of other communication modules. Specifically, the communication module and the other communication modules according to the first embodiment are inserted into and removed from slots provided on a substrate (motherboard) in the electronic device. When the communication module is inserted into the slot, a connector provided in the communication module and a connector included in the slot are connected to each other. Namely, the communication module is connected to the motherboard.

Thus, a configuration of the electronic device will be first described and then a configuration of the communication module according to the first embodiment will be described. Note that, although the communication module according to the first embodiment is mounted on the motherboard of the electronic device together with the plurality of other communication modules having the same shape and structure at high density, illustrations of the other communication modules are not omitted in the drawings attached to the specification.

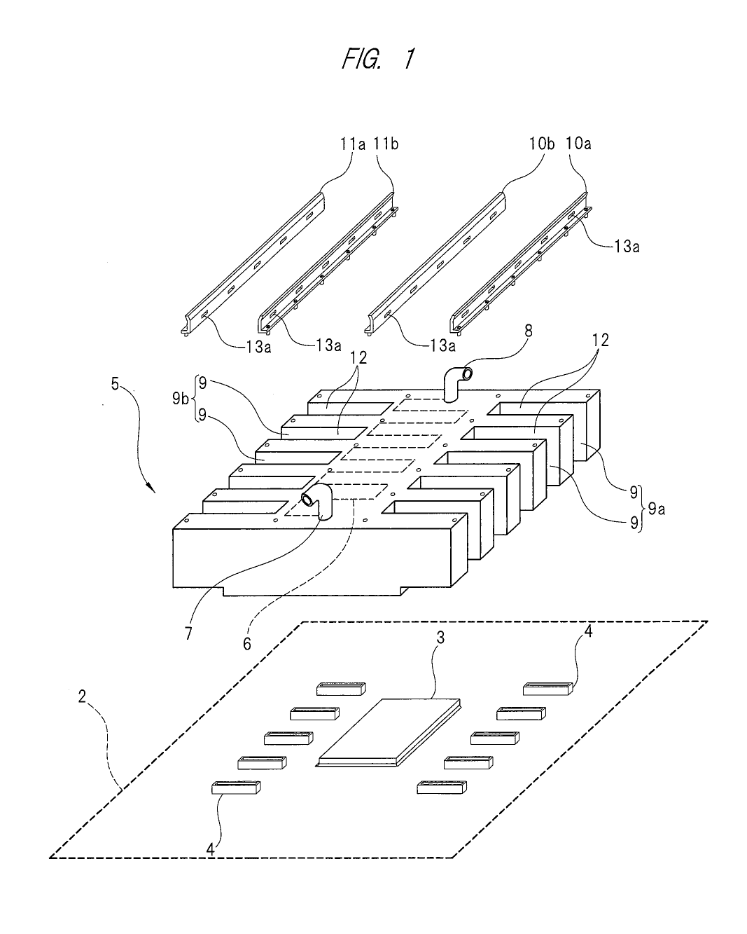

As illustrated in FIG. 1, a communication semiconductor chip 3 is mounted substantially at a center of a motherboard 2 provided in the electronic device. In addition, a plurality of connectors (receptacle connectors 4) are arranged around the communication semiconductor chip 3. Each of the receptacle connectors 4 is electrically connected to the communication semiconductor chip 3 through a wiring (not illustrated) formed on the motherboard 2.

A heat sink 5 is mounted to be superimposed on the communication semiconductor chip 3 on the motherboard 2, and an upper surface of the communication semiconductor chip 3 and a bottom surface of the heat sink 5 are in contact with each other via a heat conductive sheet (not illustrated). Namely, the communication semiconductor chip 3 and the heat sink 5 are thermally connected to each other. A refrigerant flow path 6 meandering in a zigzag manner is formed inside the heat sink 5, one end of the refrigerant flow path 6 communicates with a connection plug 7 formed on an upper surface of the heat sink 5, and the other end of the refrigerant flow path 6 communicates with another connection plug 8 formed on the upper surface of the heat sink 5. A refrigerant supply pipe (not illustrated) is connected to one connection plug 7, and a refrigerant recovery pipe (not illustrated) is connected to the other connection plug 8. A refrigerant (for example, water) is supplied through the refrigerant supply pipe and the connection plug 7 to the heat sink 5 by a pump (not illustrated) incorporated in the electronic device. The refrigerant supplied to the heat sink 5 passes through the refrigerant flow path 6, and is recovered through the connection plug 8 and the refrigerant recovery pipe in the pump. Namely, the refrigerant is circulated in the heat sink 5.

Two opposing sides of the heat sink 5 are formed in a comb-like shape so as to avoid the receptacle connectors 4. Specifically, a plurality of slits 9 are formed along one side of the heat sink 5, and a plurality of slits 9 are formed along the other side of the heat sink 5. When the heat sink 5 is mounted at a predetermined position on the motherboard 2, each of the receptacle connectors 4 is placed inside a predetermined one of the slits 9. Namely, the communication semiconductor chip 3 is covered with the heat sink 5, but the receptacle connector 4 is not covered with the heat sink 5. Specifically, three sides of each of the receptacle connectors 4 are surrounded by an internal surface of the slit 9. In other words, a plurality of slots enclosing the receptacle connectors 4 are formed on the motherboard 2 by a part of the heat sink 5. Therefore, in the following description, each slit 9 formed in the heat sink 5 is sometimes referred to as the “slot 9”. In addition, the plurality of slots 9 formed on the right side of the heat sink 5 in FIG. 1 are collectively referred to as a “right slot column 9a”, and the plurality of slots 9 formed on the left side of the heat sink 5 in FIG. 1 are collectively referred to as a “left slot column 9b” in some cases.

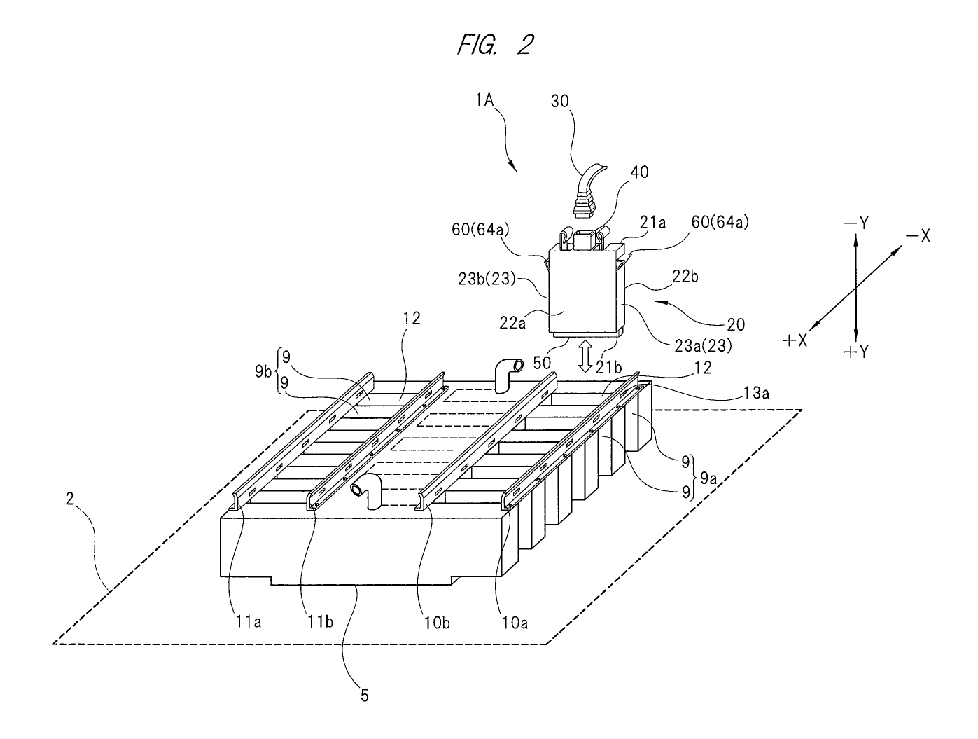

A pair of angle members 10a and 10b and another pair of angle members 11a and 11b are arranged on the upper surface of the heat sink 5. Each of the angle members 10a, 10b, 11a and 11b is screwed to the upper surface of the heat sink 5. Specifically, as illustrated in FIG. 2, the pair of angle members 10a and 10b is screwed at both sides of the right slot column 9a, and the other pair of angle members 11a and 11b is screwed at both sides of the left slot column 9b. In other words, the pair of angle members 10a and 10b opposes each other with openings 12 of the respective slots 9 included in the right slot column 9a interposed therebetween. In addition, the other pair of angle members 11a and 11b opposes each other with openings 12 of the respective slots 9 included in the left slot column 9b interposed therebetween.

A plurality of first locking portions (locking holes 13a) are formed in each of the angle members 10a, 10b, 11a and 11b along a longitudinal direction thereof, and the locking holes 13a are arranged at the same pitch with that of the slots 9. Namely, a pair of the locking holes 13a opposing each other is provided around the opening 12 of each slot 9 (at both sides of the opening 12 in the first embodiment).

Next, the communication module according to the first embodiment will be described in detail. As illustrated in FIG. 2, a communication module 1A is inserted into and removed from the slot 9 through the opening 12 of each slot 9 formed by a part of the heat sink 5.

The communication module 1A includes a housing 20 having a substantially rectangular parallelepiped shape and made of sheet metal. The housing 20 of the communication module 1A has an upper surface 21a and a bottom surface 21b opposing each other, a front surface 22a and a back surface 22b opposing each other, and a first side surface 23a and a second side surface 23b opposing each other. In the following description, the first side surface 23a and the second side surface 23b are sometimes collectively referred to as a “side surface 23”. In addition, an opposing direction of the upper surface 21a and the bottom surface 21b is defined as a “height direction”, an opposing direction of the first side surface 23a and the second side surface 23b is defined as a “width direction”, and an opposing direction of the front surface 22a and the back surface 22b is defined as a “thickness direction”. According to the definition, the communication module 1A is a low-profile module whose dimension in the thickness direction is smaller in comparison with dimensions in the height direction and the width direction.

An optical connection part 40 as a second connector which an optical fiber 30 as a communication cable is inserted into and removed from is provided in the housing 20 of the communication module 1A. In addition, a plug connector 50 as a first connector which is inserted into and removed from the receptacle connector 4 (FIG. 1) is provided in the housing 20. Further, a pair of slide members 60 and 60 whose protrusion length with respect to the housing 20 is variable is provided in the housing 20.

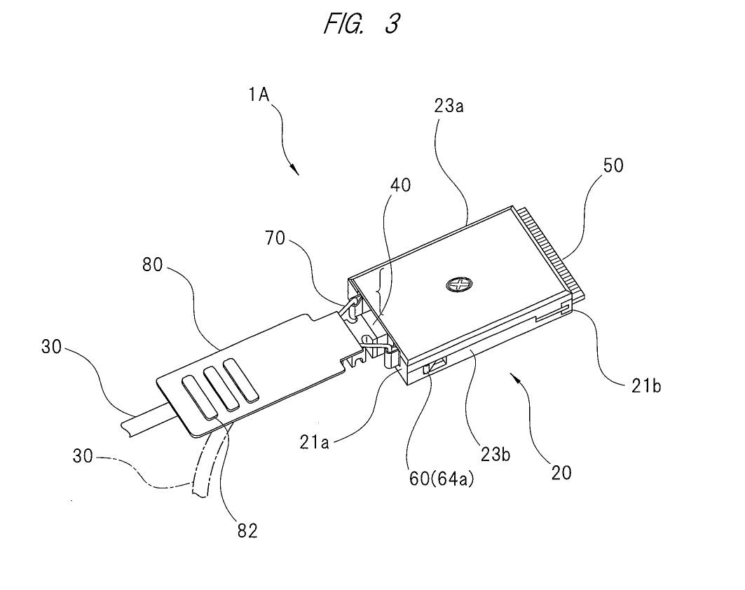

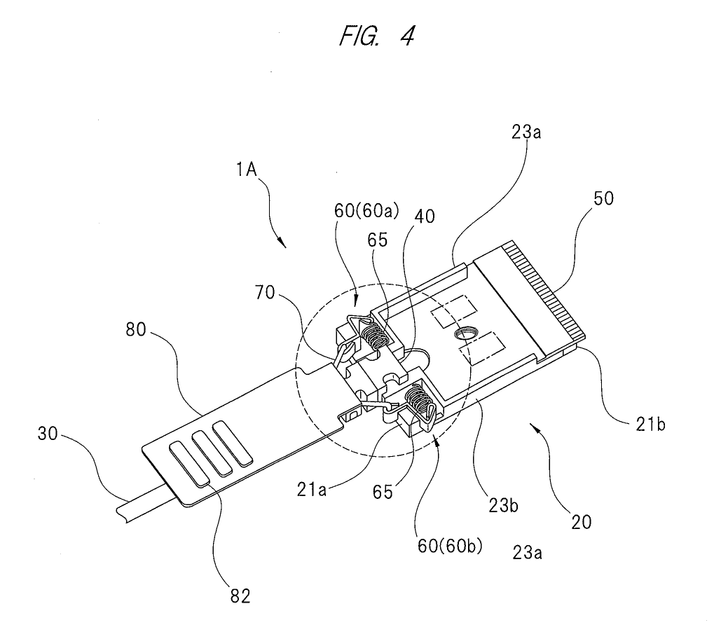

As illustrated in FIGS. 3 and 4, the plug connector 50 is an edge connector (card edge) protruding from the bottom surface 21b of the housing 20. Meanwhile, the optical connection part 40 protrudes from the upper surface 21a of the housing 20 on an opposite side of the bottom surface 21b. Namely, the optical connection part 40 as the second connector is provided on the opposite side of the plug connector 50 as the first connector.

As illustrated in FIG. 4, a part of one slide member 60 protrudes from the first side surface 23a of the housing 20 to the outside of the housing, and a part of the other slide member 60 protrudes from the second side surface 23b, which opposes the first side surface 23a, of the housing 20 to the outside of the housing. Note that, although not illustrated in FIG. 4, various elements required for implementing an optical communication function and other functions are housed in the housing 20. For example, a light emitting element, a driving element for driving the light emitting element and the like are housed in the housing 20.

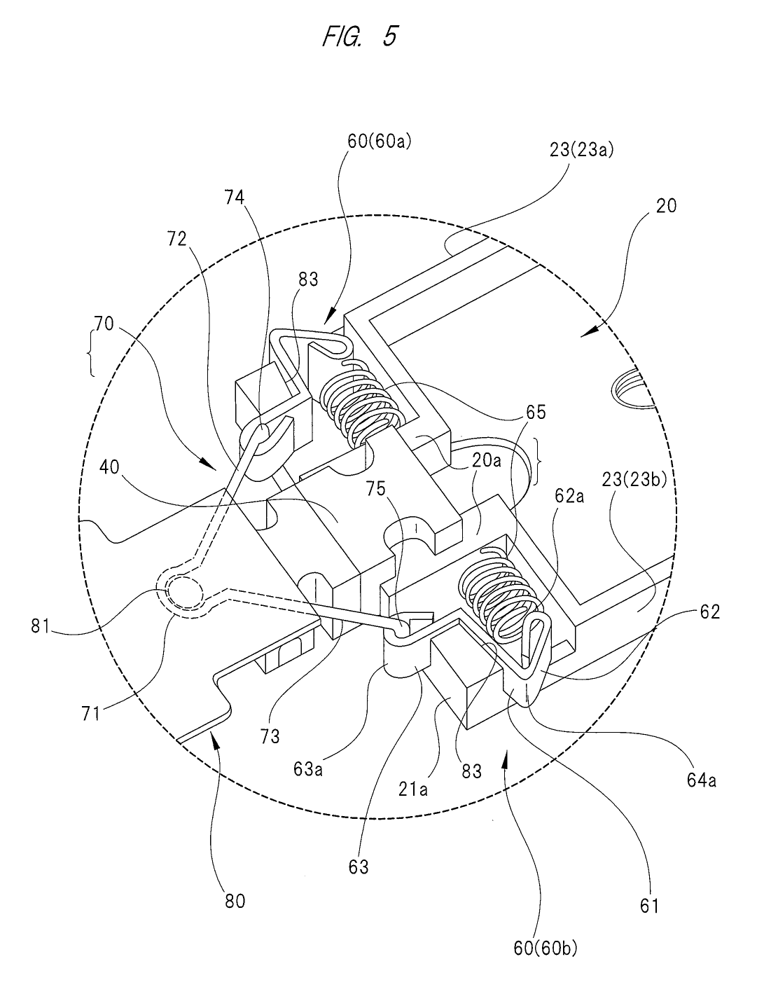

As illustrated in FIG. 5, the pair of slide members 60 and 60 is arranged at both sides of the optical connection part 40. In other words, the pair of slide members 60 and 60 opposes each other with the optical connection part 40 interposed therebetween. Each of the slide members 60 and 60 includes a horizontal portion 61 extending along the upper surface 21a of the housing 20, an inclined portion 62 obliquely extending from one end of the horizontal portion 61 toward an inner side of the housing 20, and a vertical portion 63 upstanding substantially at a right angle from the other end of the horizontal portion 61. Further, a bent portion between the horizontal portion 61 and the inclined portion 62 protrudes from the side surface 23 of the housing 20 to the outside of the housing, and forms a locking projection 64a as a second locking portion.

In addition, an end portion of the inclined portion 62 is folded back toward the inner side of the housing 20, and forms an abutting portion 62a on which one end of a coil spring 65 as an elastic member abuts. The other end of the coil spring 65 abuts on a rib 20a formed inside the housing 20. Namely, the coil spring 65 is arranged between the housing 20 and the slide member 60. Accordingly, each of the slide members 60 and 60 is constantly biased toward an outer side of the housing 20 by an elastic restoring force of the coil springs 65 and 65 interposed between each of the slide members 60 and 60 and the housing 20. In other words, when a force toward the inner side of the housing 20 larger than the elastic restoring force of the coil spring 65 acts on the slide member 60, the slide member 60 is moved to the inner side of the housing 20 against the biasing of the coil spring 65. The protrusion length of the slide member 60 with respect to the housing 20 (side surface 23) varies in accordance with the movement of the slide member 60.

Meanwhile, an end portion of the vertical portion 63 is folded back toward the inner side of the housing 20, and forms a hook portion 63a with which a coupling member 70 is locked. Details of the coupling member 70 will be described later.

Incidentally, each portion of the slide member 60 (the horizontal portion 61, the inclined portion 62, the vertical portion 63, the abutting portion 62a and the hook portion 63a) is formed by bending a single sheet metal. Namely, the horizontal portion 61, the inclined portion 62, the vertical portion 63, the abutting portion 62a and the hook portion 63a are formed integrally. Note that there is an embodiment in which the horizontal portion 61, the inclined portion 62, the vertical portion 63, the abutting portion 62a and the hook portion 63a are integrally molded from synthetic resin or other materials. Alternatively, there is also an embodiment in which all or some of the horizontal portion 61, the inclined portion 62, the vertical portion 63, the abutting portion 62a and the hook portion 63a are separately formed and are then integrated.

As illustrated in FIGS. 3 and 4, the communication module 1A includes a pull tab 80 as an operating piece, and one end of the pull tab 80 in the longitudinal direction is coupled to the pair of slide members 60 and 60 via the coupling member 70. Note that illustrations of the coupling member 70 and the pull tab 80 are omitted in FIG. 2.

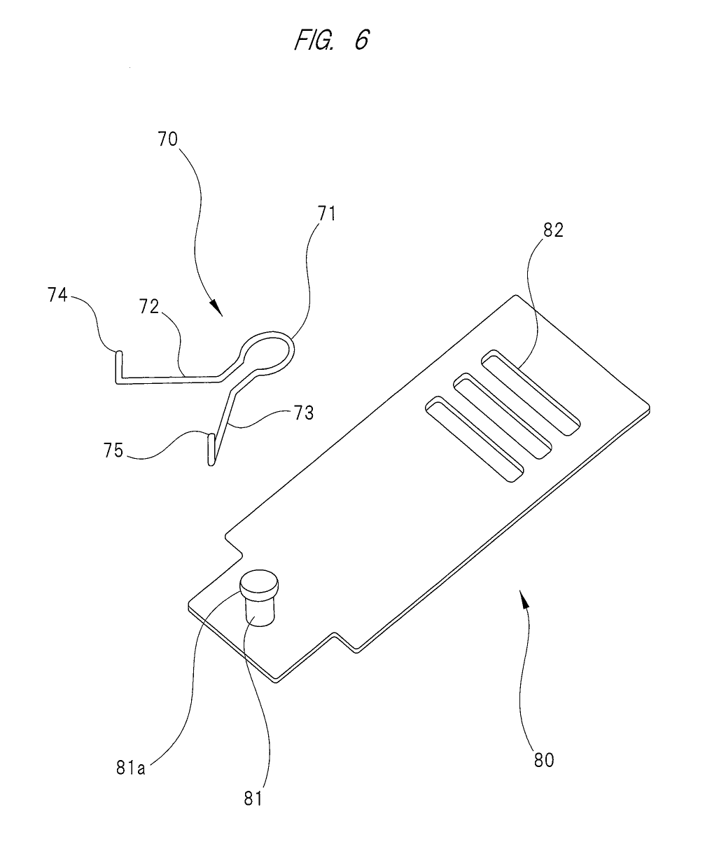

As illustrated in FIG. 6, the coupling member 70 is a wire material bent into a predetermined shape, and has a spring property (elasticity). Specifically, the coupling member 70 includes a base end portion 71 having a substantially annular shape which is opened partly, a first arm portion 72 extending linearly from one end of the base end portion 71 and a second arm portion 73 extending linearly from the other end of the base end portion 71. Further, a tip end of the first arm portion 72 is bent substantially at a right angle to forma first end portion 74, and a tip end of the second arm portion 73 is bent substantially at a right angle to forma second end portion 75. In other words, the base end portion 71 and the first end portion 74 are linked by the first arm portion 72, and the base end portion 71 and the second end portion 75 are linked by the second arm portion 73.

Here, an interval between the first arm portion 72 and the second arm portion 73 is expanded with distance from the base end portion 71. Namely, the coupling member 70 has a substantially triangular planer shape (substantially mountain-like shape) having the base end portion 71 as a vertex thereof, and the first end portion 74 and the second end portion 75 are positioned at both ends of a bottom side of the triangle. Accordingly, when a force to make the first end portion 74 and the second end portion 75 come close to each other is applied, the coupling member 70 exhibits an elastic restoring force against the force.

With reference to FIG. 5 again, the first end portion 74 of the coupling member 70 is coupled to one end of one slide member 60 at one side of the optical connection part 40. Specifically, the first end portion 74 is inserted into the hook portion 63a of the one slide member 60, and is coupled to the corresponding slide member 60. In addition, the second end portion 75 of the coupling member 70 is coupled to one end of the other slide member 60 at the other side of the optical connection part 40. Specifically, the second end portion 75 is inserted into the hook portion 63a of the other slide member 60, and is coupled to the corresponding slide member 60. Namely, the pair of slide members 60 and 60 is coupled to the common coupling member 70.

As illustrated in FIG. 6, the pull tab 80 is formed in a strip shape from synthetic resin, and a boss 81 having a substantially columnar shape is integrally formed at one end side of a rear surface of the pull tab 80 in the longitudinal direction. The coupling member 70 and the pull tab 80 are coupled to each other by fitting the boss 81 to the inside of the base end portion 71 of the coupling member 70. Namely, the pair of slide members 60 and 60 and the pull tab 80 are coupled to one another via the coupling member 70. As illustrated in FIG. 5, the first end portion 74 of the coupling member 70 is positioned at one side of the optical connection part 40, and the second end portion 75 is positioned at the other side of the optical connection part 40. Accordingly, the base end portion 71 which is a vertex of the coupling member 70 is positioned on an extension line of the optical connection part 40. Namely, the pull tab 80 is coupled to the base end portion 71 of the coupling member 70 in an insertion and removal direction of the optical fiber 30 with respect to the optical connection part 40. As a result, as illustrated in FIGS. 3 and 4, the pull tab 80 is drawn out from the housing 20 in the same direction as the optical fiber 30. In addition, as illustrated in FIG. 5, a base of the pull tab 80 is supported by the base end portion 71 and a part of the arm portions 72 and 73 of the coupling member 70. Accordingly, even when the optical fiber 30 droops as indicated by a one-dot chain line in FIG. 3, the pull tab 80 does not droop or at least does not droop at the same degree as the optical fiber 30.

With reference to FIG. 6 again, a retaining portion 81a having an outer diameter larger than an inner diameter of the base end portion 71 is formed at a tip end of the boss 81, and this prevents the boss 81 fit into the base end portion 71 from being unintentionally detached from the base end portion 71.

As described above, the communication module 1A according to the first embodiment includes the pair of slide members 60 and 60 which is movable to the inside and outside of the housing 20 and whose protrusion length with respect to the housing 20 is variable, the coil springs 65 and 65 biasing the slide members 60 and 60 toward the outer side of the housing 20, and the pull tab 80 coupled to each one end of the slide members 60 and 60 via the coupling member 70.

Next, a process of attaching and detaching the communication module 1A to and from an electronic device will be described. First, a process of attaching (mounting) the communication module 1A to an electronic device will be described. In this process, as illustrated in FIG. 2, the communication module 1A is inserted into the slot 9, and the plug connector 50 protruding from the bottom surface 21b of the communication module 1A is inserted into (connected to) the receptacle connector 4 (FIG. 1) in the slot 9. As illustrated in FIG. 2, the communication module 1A is inserted into the slot 9 from the upper side on the paper of FIG. 2, and the plug connector 50 is inserted into (connected to) the receptacle connector 4 (FIG. 1) from the same side. Namely, the up-and-down direction (±Y direction) of the paper of FIG. 2 is an insertion and removal direction of the plug connector 50 with respect to the receptacle connector 4. More specifically, +Y direction is an insertion direction (first direction) of the plug connector 50 with respect to the receptacle connector 4, and −Y direction is a removal direction (second direction) of the plug connector 50 with respect to the receptacle connector 4.

Another communication module is inserted into the slot 9 next to the slit 9 into which the communication module 1A is inserted. Further, still another communication module is inserted into the slot 9 next to the slot 9 into which the other communication module is inserted. Namely, an arrangement direction of the communication module 1A illustrated in FIG. 2 and other neighboring communication modules is a front-and-back direction (±X direction) of the paper of FIG. 2, and this direction is coincident with an arrangement direction of the slots 9, and is further coincident with the thickness direction of the communication module 1A.

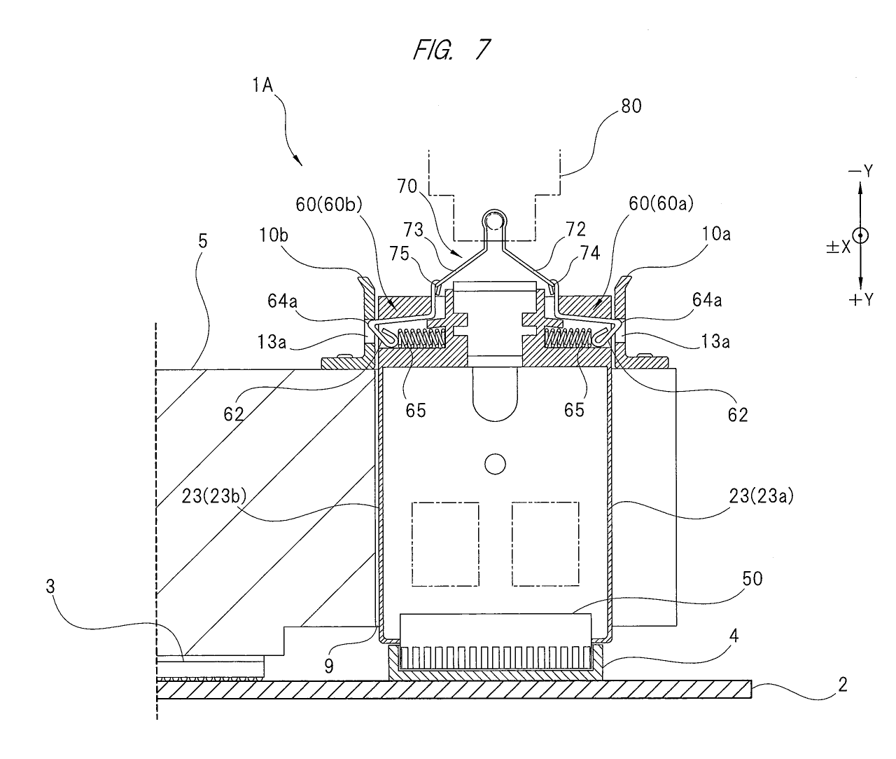

FIG. 7 illustrates an enlarged cross-section of the communication module 1A in a state where the communication module 1A is inserted into the slot 9 and the plug connector 50 is connected to the receptacle connector 4 in the above-described manner. In the following description, the slide member 60 illustrated on the right side of the paper in FIG. 7 is sometimes referred to as a “right slide member 60a” or a “slide member 60a” so as to be distinguished from the slide member 60 illustrated on the left side of the paper. In addition, the slide member 60 illustrated on the left side of the paper in FIG. 7 is sometimes referred to as a “left slide member 60b” or a “slide member 60b” so as to be distinguished from the slide member 60 illustrated on the right side of the paper. However, this is just a distinction for the convenience of description.

In the course of inserting the communication module 1A into the slot 9 in the above-described manner, the right slide member 60a abuts on an upper portion of the angle member 10a, and the left slide member 60b abuts on an upper portion of the angle member 10b. More specifically, the inclined portion 62 of the right slide member 60a abuts on the upper portion of the angle member 10a, and the inclined portion 62 of the left slide member 60b abuts on the upper portion of the angle member 10b. Then, the insertion of the communication module 1A into the slot 9 is temporarily restricted.

However, when the communication module 1A is pushed downward (in +Y direction or the first direction) more strongly, the slide members 60a and 60b are moved to the inner side of the housing 20 against the biasing of the coil springs 65 and 65 provided behind the slide members. In other words, the slide members 60a and 60b are pushed into the inner side of the housing 20, and the protrusion length of the slide members 60a and 60b with respect to the side surface 23 of the housing gradually decreases. Here, in order to smoothly move the slide members 60a and 60b to the inner side of the housing, each upper portion of the angle members 10a and 10b is inclined so as to follow each inclined portion 62 of the slide members 60a and 60b.

With the decrease of the protrusion length of the slide members 60a and 60b with respect to the side surface 23 of the housing, the communication module 1A is gradually inserted into the inside of the slot 9. Thereafter, when each locking projection 64a of the slide members 60a and 60b is moved down to a position of the locking hole 13a by the insertion of the communication module 1A into the slot 9, the slide members 60a and 60b biased by the coil springs 65 and 65 are moved toward the outside of the housing 20 again, and the respective locking projections 64a enter the corresponding locking holes 13a. Namely, the locking projections 64a provided in the communication module 1A are locked with the locking holes 13a provided in the motherboard 2. Since the slide members 60a and 60b constantly receive the biasing of the coil springs 65 and 65, the state in which the respective locking projections 64a are locked with the respective locking holes 13a is maintained, and the communication module 1A is hardly pulled out of the slot 9.

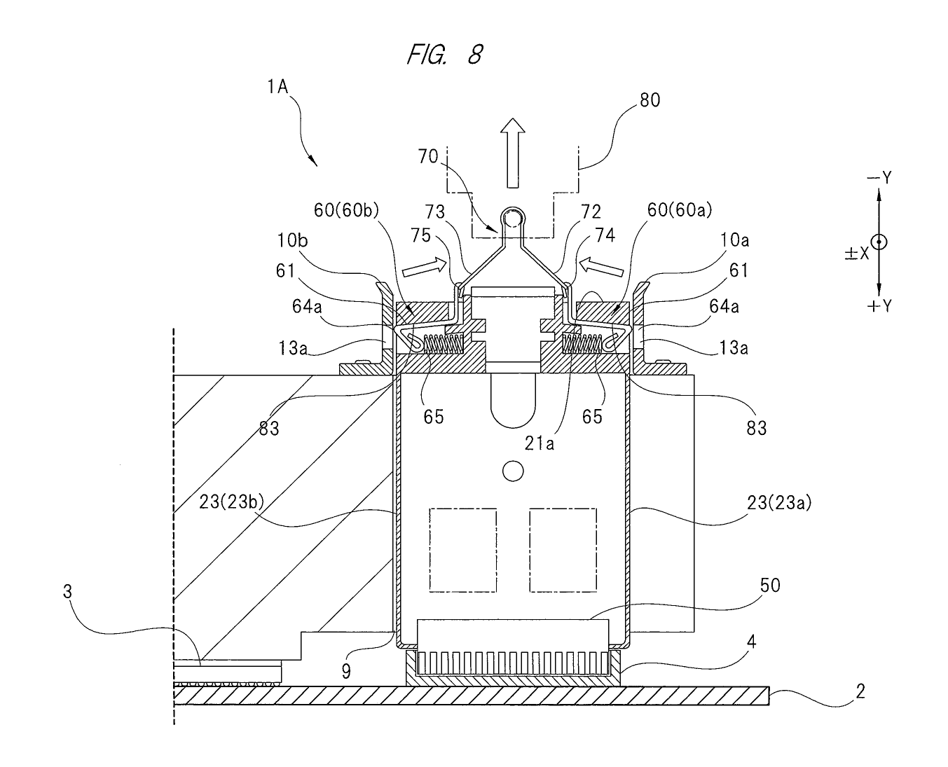

Next, a process of removing the plug connector 50 from the receptacle connector 4 and pulling the communication module 1A out of the slot 9 will be described with reference mainly to FIG. 8. The pull tab 80 illustrated in FIG. 8 is pulled upward (in −Y direction or the second direction). Such an operation of the pull tab 80 is performed by, for example, pinching an end portion (see FIG. 3) on the opposite side of an end portion of the pull tab 80 coupled to the coupling member 70 with an index finger and a thumb. Thus, in the first embodiment, slip-proof irregularities 82 are formed in the end portion of the pull tab 80.

As illustrated in FIG. 8, when the pull tab 80 is pulled upward, the coupling member 70 interposed between the pull tab 80 and the slide members 60a and 60b is elastically deformed. Specifically, the coupling member 70 is elastically deformed so that the interval between the first arm portion 72 and the second arm portion 73 is reduced and the first end portion 74 and the second end portion 75 come close to each other. Then, the right slide member 60a to which the first end portion 74 is coupled and the left slide member 60b to which the second end portion 75 is coupled are pulled to the inner side of the housing 20, and are moved to the inner side of the housing 20. Specifically, the right slide member 60a is moved to the left side of the paper against the biasing of the coil spring 65, and the left slide member 60b is moved to the right side of the paper against the biasing of the coil spring 65. In this manner, when the pull tab 80 is pulled upward (in −Y direction or the second direction), the pair of slide members 60a and 60b is drawn to the inner side of the housing 20, and each protrusion length of the slide members 60a and 60b with respect to the side surface 23 of the housing gradually decreases.

Namely, a force in the second direction applied to the pull tab 80 is converted into a force toward the inner side of the housing 20 by the coupling member 70 and is then transmitted to the slide members 60a and 60b. Here, in order to smoothly move the slide members 60a and 60b to the inner side of the housing, that is, to smoothly convert the force in the second direction applied to the pull tab 80 into the force toward the inner side of the housing, a guide surface 83 is formed inside the housing 20. The guide surface 83 is an inclined surface that abuts on the horizontal portion 61 of the slide member 60, and guides the above-described movement of the slide member 60. Specifically, the guide surface 83 is inclined upward from the outer side to the inner side of the housing 20. In other words, a distance between the upper surface 21a and the guide surface 83 of the housing 20 is gradually shortened as approaching the inner side of the housing 20.

When each protrusion length of the slide members 60a and 60b with respect to the side surface 23 of the housing decreases to a predetermined length or less, each of the locking projections 64a of the slide members 60a and 60b is disengaged from the locking hole 13a. Namely, the lock of the locking projection 64a to the locking hole 13a is released. When the pull tab 80 is continuously pulled thereafter, the plug connector 50 is removed from the receptacle connector 4, and the communication module 1A is pulled out of the slot 9.

### Second Embodiment

Hereinafter, another example of an embodiment of the communication module of the present invention will be described. Understandably, the communication module according to the second embodiment includes the same basic configuration as the communication module according to the first embodiment. Accordingly, descriptions regarding the same or substantially the same configuration as the configuration that has already been described will be omitted as appropriate.

In the communication module 1A according to the first embodiment, the end portion of the inclined portion 62 of the slide member 60 is folded back toward the inner side of the housing 20 to form the abutting portion 62a (FIG. 5). In addition, the slide member 60 is biased toward the outer side of the housing 20 by the coil spring 65 that abuts on the abutting portion 62a (FIG. 5).

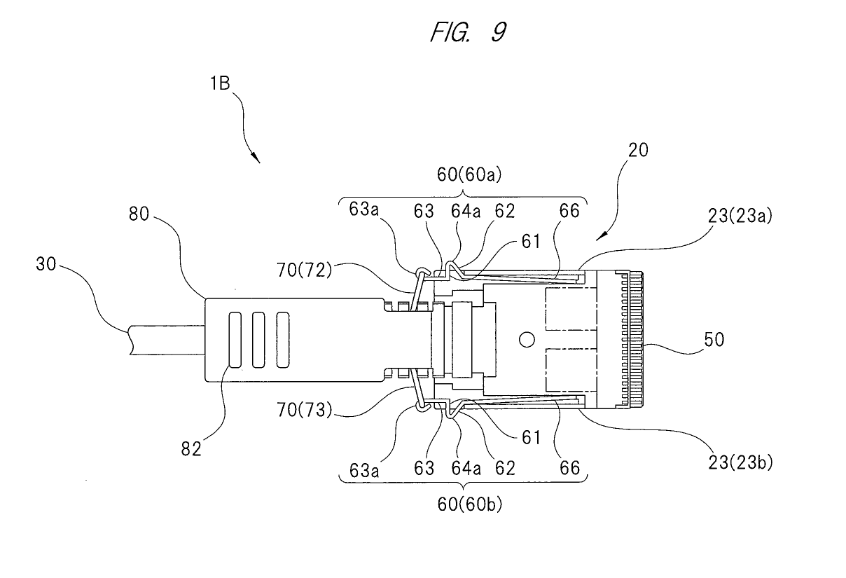

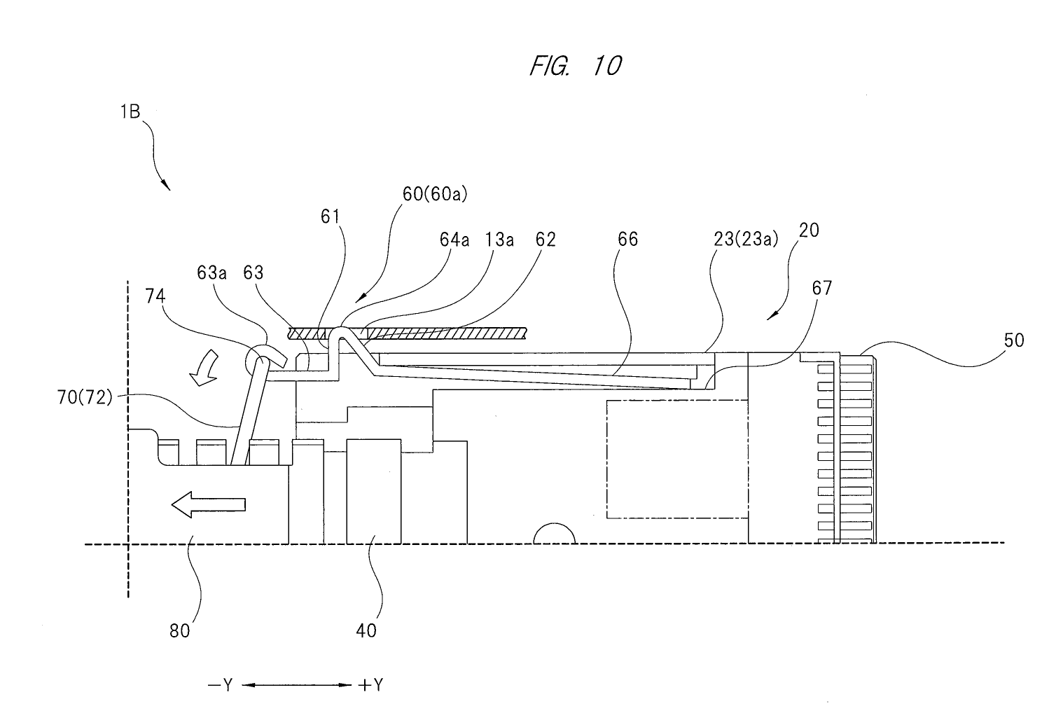

On the other hand, as illustrated in FIG. 9, no abutting portion is formed in the slide member 60 provided in a communication module 1B according to the second embodiment, and no coil spring is provided therein. As illustrated in FIG. 9, a leg portion 66 extending linearly along the side surface 23 of the housing 20 is added to a tip of the inclined portion 62 of the slide member 60. As illustrated in FIG. 10, one end of the leg portion 66 is linked to the inclined portion 62, and the other end of the leg portion 66 reaches a vicinity of the bottom surface of the housing 20. Further, the other end (tip end) of the leg portion 66 reaching the vicinity of the bottom surface of the housing 20 is interposed and fixed between an internal surface of the housing 20 and an outer surface of a module substrate 67. Namely, in the second embodiment, one end of the slide member 60 (the tip end of the leg portion 66) is configured as a fixed end.

When the pull tab 80 illustrated in FIG. 10 is pulled in −Y direction (the second direction), the coupling member 70 is elastically deformed similarly to the case of the first embodiment. Specifically, the interval between the first arm portion 72 and the second arm portion (not illustrated) of the coupling member 70 is reduced, and the first end portion 74 and the second end portion (not illustrated) come close to each other. Then, the slide member 60 illustrated in FIG. 10 rotates toward the lower side of the paper about the fixed end (the tip end of the leg portion 66) as a fulcrum, and is moved to the inner side of the housing 20. Meanwhile, the slide member to which the second end portion (not illustrated) is coupled rotates toward the upper side of the paper about the fixed end (the tip end of the leg portion) as a fulcrum, and is moved to the inner side of the housing 20. Namely, each of the right slide member 60a and the left slide member 60b illustrated in FIG. 9 is moved to the inner side of the housing 20. As a result, each protrusion length of the slide members 60a and 60b with respect to the side surface 23 of the housing decreases, and the locking projection 64a is disengaged from the locking hole 13a (FIG. 10). Namely, the lock of the locking projection 64a to the locking hole 13a is released.

### Third Embodiment

Hereinafter, still another example of an embodiment of the communication module of the present invention will be described.

Understandably, the communication module according to the third embodiment includes the same basic configuration as the communication module according to the first embodiment. Accordingly, descriptions regarding the same or substantially the same configuration as the configuration that has already been described will be omitted as appropriate.

In the first embodiment and the second embodiment, the locking hole as the first locking portion is provided in the substrate and the locking projection as the second locking portion is provided in the communication module. On the other hand, in the third embodiment, a locking piece is provided in the substrate and the locking hole is provided in the communication module. Hereinafter, a detailed description will be made.

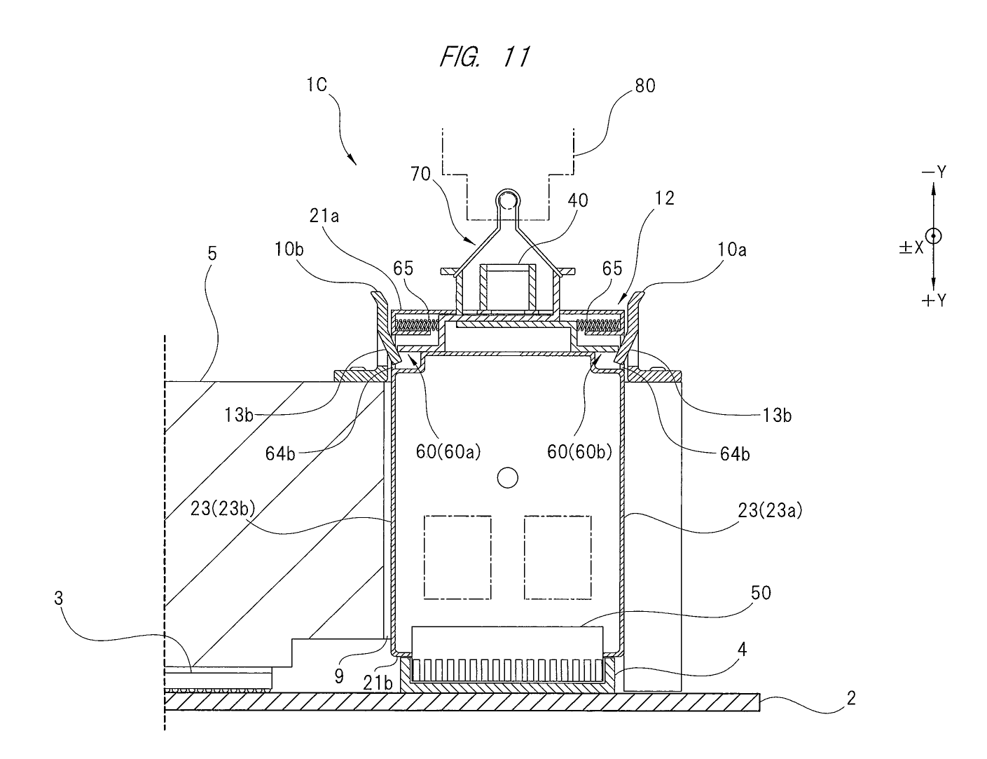

As illustrated in FIG. 11, a plurality of locking pieces 13b are formed in the angle members 10a and 10b according to the third embodiment along the longitudinal direction thereof. Although not illustrated, also in the third embodiment, two sets of angle members are provided on the upper surface of the heat sink similarly to the angle members 10a, 10b, 11a and 11b illustrated in FIG. 1, and the angle members 10a and 10b illustrated in FIG. 11 are one of the two sets of angle members. In addition, the locking pieces 13b illustrated in FIG. 11 are formed at the same positions as the locking holes 13a illustrated in FIG. 1. Namely, in the third embodiment, a pair of the locking pieces 13b opposing each other is provided around the opening 12 (at both sides of the opening 12) of each slot 9.

The locking pieces 13b and 13b illustrated in FIG. 11 are a part of the angle members 10a and 10b bent toward an inner side in the width direction of the opening 12, and have flexibility. Accordingly, when each locking piece 13b is pressed toward an outer side in the width direction of the opening 12, it is flexed in the same direction, and when the locking piece 13b is released from the pressing, it returns to an original state (position) by an elastic restoring force. Namely, when a pressing force toward the outer side in the width direction of the opening 12 acts on each of the opposing locking pieces 13b and 13b, an opposing interval between these locking pieces 13b and 13b increases. On the other hand, when the locking pieces 13b and 13b are released from the pressing, the opposing interval between the locking pieces 13b and 13b returns to an original interval.

As illustrated in FIG. 11, a communication module 1C according to the third embodiment also includes the pair of slide members 60 and 60. In the following description, one of the slide members 60 is sometimes referred to as the “right slide member 60a” or the “slide member 60a”, and the other slide member 60 is sometimes referred to as the “left slide member 60b” or the “slide member 60b” for distinction. However, this is just a distinction for the convenience of description.

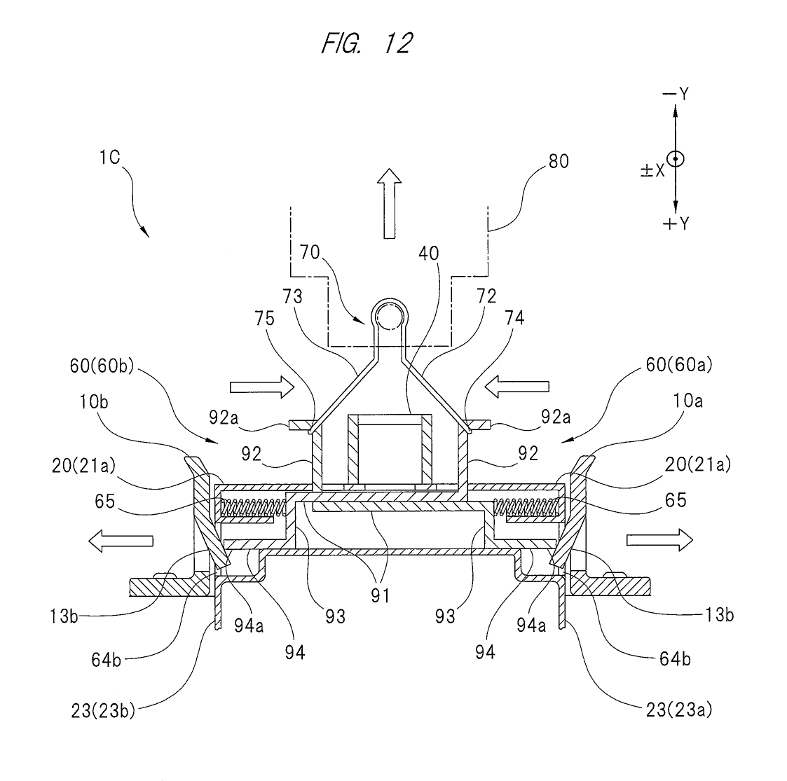

As illustrated in FIG. 12, each of the right slide member 60a and the left slide member 60b includes a first horizontal portion 91 extending along the upper surface 21a of the housing 20, a first vertical portion 92 extending upward from one end of the first horizontal portion 91 and penetrating the upper surface 21a of the housing 20, a second vertical portion 93 extending from the other end of the first horizontal portion 91 toward the bottom surface 21b (FIG. 11) of the housing 20, and a second horizontal portion 94 extending from an end portion of the second vertical portion 93 toward the side surface 23 of the housing 20.

An end portion of the first vertical portion 92 which is one end of each of the slide members 60a and 60b is bent outward to form a hook portion 92a, so that the first end portion 74 of the coupling member 70 is coupled to the hook portion 92a of the right slide member 60a and the second end portion 75 of the coupling member 70 is coupled to the hook portion 92a of the left slide member 60b. In addition, an end portion of the second horizontal portion 94 which is the other end of each of the slide members 60a and 60b is arranged inside a locking hole 64b formed in the side surface 23 of the housing 20 to form a pressing portion 94a.

Understandably, each portion of the slide members 60a and 60b (the first horizontal portion 91, the first vertical portion 92, the hook portion 92a, the second vertical portion 93, the second horizontal portion 94 and the pressing portion 94a) is a part of sheet metal bent in a stepwise manner. Namely, the first horizontal portion 91, the first vertical portion 92, the hook portion 92a, the second vertical portion 93, the second horizontal portion 94 and the pressing portion 94a are formed integrally.

The right slide member 60a and the left slide member 60b are combined with each other in a superimposed manner. Specifically, the first horizontal portion 91 of the right slide member 60a is superimposed on the first horizontal portion 91 of the left slide member 60b. Further, a slit is formed in a lower portion of the first vertical portion 92 of the left slide member 60b, and the first horizontal portion 91 of the right slide member 60a penetrates this slit and protrudes to the back of the first vertical portion 92 of the left slide member 60b. In addition, the first horizontal portion 91 of the left slide member 60b passes under the first vertical portion 92 of the right slide member 60a and protrudes to the back of the first vertical portion 92. Accordingly, the pressing portion 94a of the right slide member 60a is positioned on a left side of the optical connection part 40, while the hook portion 92a is positioned on a right side of the optical connection part 40. In addition, the pressing portion 94a of the left slide member 60b is positioned on a right side of the optical connection part 40, while the hook portion 92a is positioned on a left side of the optical connection part 40. Note that the slide members 60a and 60b are schematically illustrated in FIGS. 11 and 12. In practice, each first horizontal portion 91 of the slide members 60a and 60b has a shape for avoiding interference with the optical connection part 40 or is arranged so as to avoid the interference.

As illustrated in FIG. 12, two elastic members (the coil springs 65) are housed in the housing 20. One coil spring 65 is arranged between the second vertical portion 93 of the right slide member 60a and the second side surface 23b of the housing 20, and the other coil spring 65 is arranged between the second vertical portion 93 of the left slide member 60b and the first side surface 23a of the housing 20. The right slide member 60a is constantly biased to the right side by the coil spring 65, and the left slide member 60b is constantly biased to the left side by the coil spring 65. Understandably, since each first vertical portion 92 of the slide members 60a and 60b abuts on the housing 20, the right slide member 60a does not move to the right side relative to the position illustrated in FIG. 12, and the left slide member 60b does not move to the left side relative to the position illustrated in FIG. 12. Namely, the positions illustrated in FIG. 12 are initial positions of the right slide member 60a and the left slide member 60b. When the right slide member 60a and the left slide member 60b are at the initial positions, an interval between the two opposing hook portions 92a with the optical connection part 40 interposed therebetween becomes the largest, and an interval between the two pressing portions 94a becomes the smallest. At this time, each pressing portion 94a recedes inside the housing 20. In other words, when the right slide member 60a and the left slide member 60b are at the initial positions, the two pressing portion 94a are retracted inside the housing 20.

When the pull tab 80 illustrated in FIG. 12 is pulled upward (in −Y direction or the second direction), the coupling member 70 is elastically deformed similarly to the case of the first embodiment. Specifically, the interval between the first arm portion 72 and the second arm portion 73 of the coupling member 70 is reduced, and the first end portion 74 and the second end portion 75 come close to each other. Then, a force toward the inner side of the housing 20 is transmitted to one ends (the hook portions 92a) of the slide members 60a and 60b, so that the right slide member 60a is moved to the left side of the paper as a whole against the biasing of the coil spring 65 and the left slide member 60b is moved to the right side of the paper as a whole against the biasing of the coil spring 65. At this time, the one ends (the hook portions 92a) of the slide members 60a and 60b are moved in directions opposite to each other toward the inner side of the housing 20, and the other ends (the pressing portions 94a) of the slide members 60a and 60b are moved in directions opposite to each other toward the outer side of the housing 20. In other words, the one ends (the hook portions 92a) of the slide members 60a and 60b come close to each other, while the other ends (the pressing portions 94a) of the slide members 60a and 60b separate from each other.

In short, when a force in the second direction is applied to the pull tab 80, this force is converted into a force toward the inner side of the housing 20 and is then transmitted to the crossing slide members 60a and 60b, and these slide members 60a and 60b slide in the directions opposite to each other. As a result, the locking piece 13b, which has entered the locking hole 64b formed in the second side surface 23b of the housing 20, is pushed out by the pressing portion 94a of the right slide member 60a and is disengaged from the locking hole 64b. In addition, the locking piece 13b, which has entered the locking hole 64b formed in the first side surface 23a of the housing 20, is pushed out by the pressing portion 94a of the left slide member 60b and is disengaged from the locking hole 64b. In this manner, the lock of the locking piece 13b to the locking hole 64b is released.

As described above, the operating piece is provided in the housing of the communication module to which the present invention is applied. Further, the force applied to the operating piece is converted into the force toward the inner side of the housing, and the fixation between the communication module and the substrate is released by the force. Further, the direction of the force applied to the operating piece is coincident or substantially coincident with the removal direction of the first connector provided in the communication module. Accordingly, even in a state in which a plurality of communication modules are mounted at high density, the fixation of the communication module to the substrate is released just by pulling the operating piece, and the connector provided in the communication module is removed from the connector on the substrate.

The present invention is not limited to the above-described embodiments, and various modifications are possible within the scope not departing from a gist thereof. For example, although the locking hole as the first locking portion is provided outside the slot in the first embodiment and the second embodiment, the first locking portion may be provided inside the slot.

In addition, there is also an embodiment in which the slots 9 are formed on all sides of the heat sink 5 illustrated in FIG. 1 and others and the communication modules are inserted into the respective slots 9. Further, there is also an embodiment in which the slots 9 are formed on three sides of the heat sink 5. Furthermore, there is also a case in which the communication modules are inserted into only some of the slots provided in the electronic device and the other slots are empty slots. In addition, there is also an embodiment in which the slots are formed of a member different from the heat sink. Understandably, the slot is not an essential component of the present invention. For example, the first locking portion and the locking piece may be provided on the substrate by directly attaching the angle member or the like to the substrate. Namely, the first locking portion and the locking piece may be directly provided in the substrate, and may be indirectly provided. The latter case includes an aspect in which the first locking portion and the locking piece are provided in a certain member (for example, the heat sink in the above-described embodiments) attached to the substrate.

The first locking portion is not necessarily a hole, but may be a concave portion, a convex portion, a groove or the like with which the second locking portion is lockable and unlockable. In addition, there is also an embodiment in which the connector provided on the substrate is the plug connector and the first connector provided in the communication module is the receptacle connector.

The material of the coupling member is not limited to metal, and may be, for example, synthetic resin.

A light receiving element and an amplifier element are housed inside the housing instead of the light emitting element and the driving element in some cases. Also, a light receiving element and an amplifier element are housed in addition to the light emitting element and the driving element in some cases. Further, the present invention can be applied not only to an optical communication module but also to a telecommunication module, and the same operational effects as those described above can be obtained also when the present invention is applied to the telecommunication module. In the telecommunication module to which the present invention is applied, an electrical connection part is provided instead of the optical connection part 40 illustrated in FIG. 3 and others, and a telecommunication cable is connected to the electrical connection part. In addition, various elements required for implementing a telecommunication function and other functions are housed inside the housing.

What is claimed is:

1. A communication module mounted on a substrate together with a plurality of other communication modules, the communication module comprising:
a housing having a first connector which is inserted in a first direction into a connector provided on the substrate and is removed in a second direction opposite to the first direction;
a pair of slide members whose protrusion length with respect to the housing is variable and which has second locking portions that are lockable and unlockable with first locking portions that are directly or indirectly provided in the substrate; and
an operating piece coupled to one ends of the respective slide members via a coupling member,
wherein the coupling member converts a force in the second direction applied to the operating piece into a force toward an inner side of the housing and transmits the converted force to the respective slide members, thereby moving the slide members to an inner side of the housing.

2. The communication module according to claim 1, further comprising:
elastic members which bias the respective slide members toward an outer side of the housing,
wherein the coupling member converts a force in the second direction applied to the operating piece into a force toward an inner side of the housing and transmits the converted force to the respective slide members, thereby moving the slide members to an inner side of the housing against the biasing of the elastic members.

3. The communication module according to claim 1,
wherein the communication module is inserted into and removed from a slot that is provided on the substrate and encloses the connector, and
the first locking portions are provided around an opening of the slot which the communication module is inserted into and removed from.

4. A communication module mounted on a substrate together with a plurality of other communication modules, the communication module comprising:
a housing having a first connector which is inserted in a first direction into a connector provided on the substrate and is removed in a second direction opposite to the first direction;
a pair of locking holes which is provided in the housing and which locking pieces directly or indirectly provided on the substrate can enter and can be disengaged from;
a pair of slide members which is provided in the housing and is movable to inside and outside of the housing; and
an operating piece coupled to one ends of the respective slide members via a coupling member,
wherein the coupling member converts a force in the second direction applied to the operating piece into a force toward an inner side of the housing and transmits the converted force to the one ends of the respective slide members, thereby moving the one ends of the slide members to an inner side of the housing, and
the other ends of the respective slide members whose one ends are moved to the inner side of the housing are moved to an outer side of the housing, thereby disengaging the locking pieces from the locking holes.

5. The communication module according to claim 4,
wherein the communication module is inserted into and removed from a slot that is provided on the substrate and encloses the connector, and
the locking pieces are provided around an opening of the slot which the communication module is inserted into and removed from.

6. The communication module according to claim 1,
wherein the coupling member includes:
a base end portion to which the operating piece is coupled;
a first end portion to which the one end of one of the slide members is coupled;
a second end portion to which the one end of the other slide member is coupled;
a first arm portion linking the base end portion and the first end portion; and
a second arm portion linking the base end portion and the second end portion,
an interval between the first arm portion and the second arm portion is expanded with distance from the base end portion, and
the coupling member is elastically deformed so that the first end portion and the second end portion come close to each other when a force in the second direction is applied to the base end portion.

7. The communication module according to claim 6, further comprising:
a second connector which is provided on an opposite side of the first connector and which a communication cable is inserted into and removed from,
wherein the pair of slide members is arranged at both sides of the second connector,
the one end of one of the slide members is coupled to the first end portion of the coupling member at one side of the second connector,
the one end of the other slide member is coupled to the second end portion of the coupling member at the other side of the second connector, and
the operating piece is coupled to the base end portion of the coupling member in an insertion and removal direction of the communication cable.

8. The communication module according to claim 1,
wherein inclined guide surfaces which abut on the respective slide members and guide movement of the slide members are provided in the housing.

9. The communication module according to claim 4,
wherein the coupling member includes:
a base end portion to which the operating piece is coupled;
a first end portion to which the one end of one of the slide members is coupled;
a second end portion to which the one end of the other slide member is coupled;
a first arm portion linking the base end portion and the first end portion; and
a second arm portion linking the base end portion and the second end portion,
an interval between the first arm portion and the second arm portion is expanded with distance from the base end portion, and
the coupling member is elastically deformed so that the first end portion and the second end portion come close to each other when a force in the second direction is applied to the base end portion.

10. The communication module according to claim 4,
wherein inclined guide surfaces which abut on the respective slide members and guide movement of the slide members are provided in the housing.
